(19) United States
(12) Patent Application Publication
(10) Pub. No.: US 2025/0125124 A1
(43) Pub. Date: Apr. 17, 2025

(54) ELECTRON BEAM-INDUCED AND REMOTE PLASMA-ASSISTED SIMULTANEOUS MATERIAL-SELECTIVE ETCHING AND GROWTH

(71) Applicant: University of Maryland, College Park, College Park, MD (US)

(72) Inventors: Gottlieb S. Oehrlein, Clarksville, MD (US); Yudong Li, Hyattsville, MD (US)

(21) Appl. No.: 18/912,887

(22) Filed: Oct. 11, 2024

Related U.S. Application Data
(60) Provisional application No. 63/589,749, filed on Oct. 12, 2023.

(51) Int. Cl. H01J 37/32

(52) U.S. Cl. CPC H01J 37/32678; H01J 2237/3151; H01J 2237/3341

(57) ABSTRACT

A method of material-selective etching and growth includes providing an electron beam (EB) source and providing a remote plasma (RP) source. The EBsource and the RP source are applied simultaneously to a device comprising a first material of a first selected area and a second material of a second selected area, wherein the simultaneous application of electron beam irradiation from the EB source and the chemical fluxes from the RP source performs etching of the first material and growth of a third material on the second material by chemical conversion.

### CROSS REFERENCE TO RELATED APPLICATIONS

This application claims the benefit of U.S. Application Ser. No. 63/589,749 filed on Oct. 12, 2023, the entire contents of which are incorporated herein.

### TECHNICAL FIELD

The present disclosure generally relates to substrate etching. More specifically, certain examples described in the present disclosure generally relate to apparatuses, systems, and/or methods for electron beam-induced and remote plasma-assisted simultaneous material-selective etching and growth. Additional aspects and examples are included in the detailed description and figures.

### BACKGROUND

As manufacturing technology enters the sub-10 nm scale, nanofabrication processes to precisely pattern devices are getting more complex. Innovative approaches that integrate multiple processes into one step are of great benefit to control the manufacturing cost and processing time and simplify the whole process.

### SUMMARY

The present disclosure provides an approach that is based on the integration of an Electron Beam (EB) source and a Remote Plasma (RP) source and is capable of simultaneously inducing material growth and etching on two different materials without masking, respectively. This process achieves infinite etching or growth selectivity and etching or growth can be localized by the location of the EB. The ability to achieve materials etching and growth in a single process combining EB and RP from this approach can simplify semiconductor processing and significantly reduce the manufacturing cost. In conventional ion-based plasma etching, ion bombardment with large energy inevitably introduces damage to the surface, resulting in a compromised device performance. By exploiting a remote plasma source, ions are eliminated, and only reactive neutrals can reach and functionalize the surface. The EB interacts with the modified surface and initiates material etching or growth. Surface damage induced by ion bombardment is avoided. Moreover, the integration of the RP source can activate the precursor by dissociation and related processes, allowing for a broader selection of precursor reactants than commonly practiced EB induced deposition or etching (EBID and EBIE) which rely on the spontaneous adsorption of a precursor gas on the targeted material. By using such a configuration, it is demonstrated that using a single set of precursors, i.e., Ar/O₂, it is possible to induce etching of a Ru surface and oxide growth on a Ta surface when exposed to EB irradiation in the presence of radicals produced by an Ar/O₂ RP. By pulsing a small amount of CF₄ to the Ar/O₂ RP, Ru etching can be enhanced. By cycling between the Ar/O₂ etching or growth step and the Ar/O_{2/}CF₄ passivation step, the Ru etching rate (ER) ultimately surpassed the Ta thickness loss rate, selectivity of Ru over Ta loss rate is achieved, while at the same time converting the metallic Ta lost into oxidized Ta, an insulator.

In summary, the approach exploits the combination of EB and RP to achieve highly controllable and selective material etching and growth effects for a surface comprising or consisting of exposed Ru and Ta surface elements while minimizing surface damage. Material surface properties can be independently tailored by RP, and material etching or growth can be temporally and spatially controlled by the EB. This new approach can be applied to processes where highly materials selective etching or growth is required, such as photomask repair, patterning of etch stop or hard masks, deposition of a diffusion barrier layer, and others. This self-aligned process can simplify microelectronics fabrication since materials etching or growth is controlled by the nature of the exposed surface, i.e., Ru versus Ta. Additionally, the present approach enables net etching of one material and chemical transformation of another material in the same process.

In various embodiments, some methods and apparatus described herein may incorporate techniques described in US Patent Publication No. 2023/0059730, which is incorporated by reference herein as if fully set forth.

Other aspects, features and embodiments of the present disclsoure will be more fully apparent from the ensuing disclosure and appended claims.

### BRIEF DESCRIPTION OF FIGURES

In order to better understand the subject matter that is disclosed herein and to exemplify how it may be carried out in practice, embodiments will now be described, by way of non-limiting example, with reference to the accompanying drawings. With specific reference to the drawings, it is stressed that the particulars shown are by way of example and for purposes of illustrative discussion of embodiments of the disclosure.

FIG. 1 is a flow diagram of an example method of simultaneous maskless selective material etching and growth induced by electron beam (EB) and remote plasma (RP) compared to a conventional processing approach, in accordance with an embodiment;

FIG. 2 is an example diagram showing material-induced etching stop enabled by the combining of EB and RP, in accordance with an embodiment;

FIG. 3 is an example schematic diagram of a system for providing an EP and an RP source, in accordance with an embodiment;

FIG. 4 is a graphical representation of a thickness change of Ru and RuO₂ during sequential treatment of EB and RP, in accordance with an embodiment;

FIG. 5A is a graphical representation of a thickness profile of Ta, Ta₂O₅ and the sum of the two during the concurrent EB and RP exposure, in accordance with an embodiment;

FIG. 5B is a graphical representation of a Ta loss rate and Ta₂O₅ growth rate during the concurrent EB and RP or RP only exposure, in accordance with an embodiment;

FIG. 6 is a flow diagram of an example method of a cyclic process combining alternative Ar/O₂ EB/RP and Ar/O₂/CF₄ RP, in accordance with an embodiment;

FIG. 7A is a graphical representation of total thickness change of Ru and Ta during the alternative Ar/O₂ EB/RP and Ar/O₂/CF₄ RP, in accordance with an embodiment; and

FIG. 7B is a graphical representation of a thickness loss rate of Ru and Ta vs. processing cycle, in accordance with an embodiment.

### DETAILED DESCRIPTION

The subject matter of the present disclosure includes the information and references presented herein. Such references are hereby incorporated by reference each in their respective entirety, except for any statement contradictory to the express disclosure herein, except for subject matter disclaimers or disavowals, and except to the extent that the incorporated material is inconsistent with the express disclosure herein, in which case the express language of this disclosure controls. Incorporation or citation of any such reference shall not be considered an admission by the applicant that the incorporated material is prior art to the present disclosure or considered material to patentability of the present disclosure.

The present disclosure describes various aspects and illustrations by way of example and without limitation. As such, those skilled in the art will appreciate that various adjustments and modifications can be made without departing from the spirit and scope of the present disclosure. Accordingly, the breadth and scope of the present disclosure shall not be limited exclusively to the various examples provided herein.

Unless defined otherwise, all technical and scientific terms used herein have the same meanings as commonly understood by those skilled in the art to which the present disclsoure belongs. Any methods and materials similar or equivalent to those described herein can be used in the practice or testing of the disclosed methods and compositions. All publications and patents specifically mentioned herein are incorporated by reference for all purposes including describing and disclosing the chemicals, cell lines, vectors, animals, instruments, statistical analysis and methodologies which are reported in the publications which might be used in connection with the subject matter of the present disclosure.

The semiconductor industry has made essential progress in the past decades. As the feature size on a semiconductor chip reaches the sub-10 nm scale, technological advances enabling the continuation of feature scaling and extension of the Moore's law are challenging. The manufacture of the complex features on a semiconductor device requires a series of patterning processes, such as photolithography, etching, deposition, etc. As a result, the manufacture cost and the time consumed increase exponentially with the number of patterning steps, impeding the development of the semiconductor industry. One of the key challenges is to simplify the overall process flow. Selective etching and deposition, with the ability to selectively control the topography, are crucial in the patterning of semiconductor devices. The manufacture of modern semiconductor devices usually involves etching and deposition in separate steps, which consumes extra time and cost. The realization of simultaneous etching and materials growth in a single step can be greatly beneficial to the industry in terms of both economic and timely efficiency.

In plasma etching, material selective etching can be achieved by leveraging the chemical properties of the precursor and surface resulting in the etch rate (ER) of one material being higher than that of other materials. Plasma atomic layer etching (ALE), where the precursor injection and ion bombardment steps are separate, has shown the ability to realize material selective etching with atomic scale control. Fluorocarbon (FC) and hydrofluorocarbon (HFC) precursor-based selective ALE has been studied. During the precursor injection step, a thin FC film is formed on the surface that is modified. During the etching of the material, the FC film can be removed along with an activated thin underlying material and a new layer of material can be exposed to the next ALE cycle. XPS and optical studies revealed that the properties of the FC thin film, i.e., the chemical composition and thickness, varied with the underlying materials and the precursors, consequently, different removal rates are developed. By optimizing the processing, the FC layer can be removed on the etched material but can accumulate on the inert material and form a passivation layer to impede etching, realizing high selectivity material etching. However, the ion bombardment, although with low ion energy, can introduce damage to the surface. An alternative approach that can selectively etch the targeted materials will be necessary in a damage-free process. Electron beam induced etching (EBIE) is a promising approach to reduce surface damage during etching, since the etching is induced by electron irradiation rather than ion bombardment. However, the selection of the precursor reactants is limited in EBIE since precursors are not pre-activated as in the plasma-induced etching. In other examples, an approach of combing an electron beam (EB) source and remote plasma (RP) source for material etching may be utilized. The RP source activates the precursor gas, and the reactive neutrals migrate to and functionalize the surface, while the ions are eliminated. By optimizing the precursor chemistry, selective and damage-free material etching can be achieved with a broader selection of precursors.

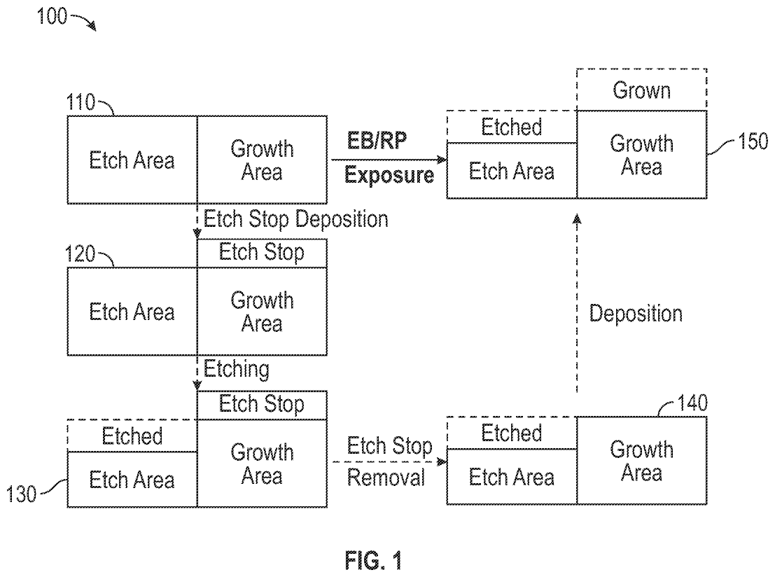

Described herein is an approach and method to realize selective material growth and etching with minimum damage in a single process by using particle fluxes that are generated by the integration of an EB and RP source. By using a single set of precursors, simultaneous inducement of etching of one material and growth of another one by chemical transformation is achieved. FIG. 1 is a flow diagram of an example method 100 of simultaneous selective material etching and growth induced by electron beam (EB) and remote plasma (RP) compared to a conventional processing approach, in accordance with an embodiment. This enables infinite etching or growth selectivity and simplifies the process flow (e.g., elements 110 and 150) compared to the conventional process as shown in elements 110, 120, 130 and 140, as illustrated in FIG. 1. Micropatterning usually involves materials etching and growth, which are implemented in a series of separate steps. By applying the EB and RP simultaneously for materials, material selective etching and growth can be realized in the same step. This kind of material-dependent outcome can be useful for simplification of patterning processes and reduce fabrication cost since it eliminates one lithographic step. The material surface chemistry can be controlled by RP and the EB induces and localizes material etching or growth. The application is exemplificd by simultaneously etching Ru and growing a dielectric Ta oxide on Ta metal resulting from the EB-induced oxidation of the surface Ta to a depth to cause the growth. This approach can be applied to processes where selective material etching or growth is desired, such as photomask repair, patterning of etch stop or hard masks, deposition of a diffusion barrier layer, and others. This self-aligned process can simplify nanofabrication process since materials etching or growth can occur at the same time. For instance, in order to mitigate the edge placement errors (EPC) during the patterning of vias, multiple steps of materials etching and growth are required to recess metals, etch dielectric layers and deposit barrier or etch stop layers.

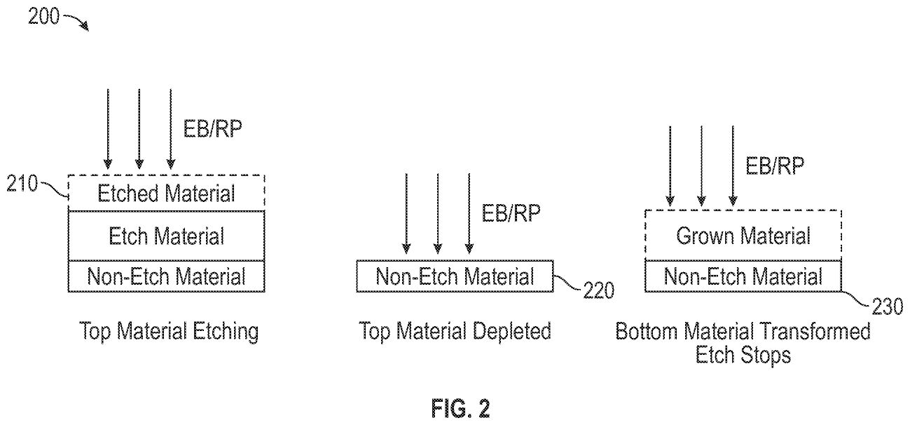

By utilizing the simultaneous materials etching and growth ability of this approach, process flow can be more efficient. Besides, this approach can be applied to processes where etching stop is required after the top material is removed, since EB/RP could induce material growth rather than etching on the bottom material, as shown in FIG. 2, which is an example diagram showing material-induced etching stop enabled by the combining of EB and RP 200, in accordance with an embodiment. Top material etching is achieved at element 210, the top metal is depleted at element 220, and the bottom material is transformed at clement 230. In conventional methods, etching stop is implemented by depositing a mask layer between the two materials which costs extra steps. The characteristic of material growth on the growth area while material being etched on the non-growth area can complement the conventional nanofabrication approach.

In various embodiments, the EB source is applied at a material penetration depth to cause the growth. In various embodiments, the EB source and the RP source are applied simultaneously to a device comprising a first material of a first selected area and a second material of a second selected area, wherein the simultaneous application of electron beam irradiation from the EB source and the chemical fluxes from the RP source performs etching of the first material and growth of a third material on the second material by chemical conversion. In various embodiments, the first selected area and the second selected area may be non-contiguous, and in other various embodiments, the the first selected area and the second selected area may be contiguous.

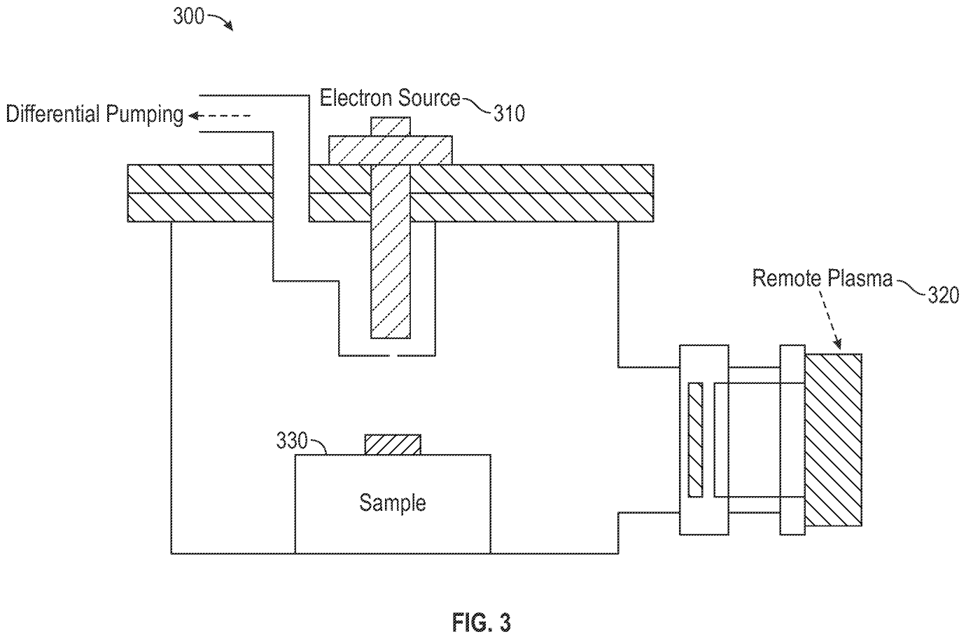

FIG. 3 is an example schematic diagram of a system 300 for providing an EP and an RP source, in accordance with an embodiment. The system 300 includes an EB source 310 and a RP source 320 to etch/grow materials on a sample 330. In various embodiments, the electron source is a commercial electron flood gun, providing a focused EB with adjustable parameters, but is not limited to this kind of EB source. The EB energy used for this embodiment is 1 keV and the emission current is 0.3 mA, which can be flexibly changed for this application. Since the electron flood gun requires a lower vacuum to operate, a differential pumping unit (DPU) may be installed to evacuate the electron source. The DPU might not be necessary, depending on the requirement of the working condition of the specific electron source. For the RP source, an electron cyclotron wave resonance (EWCR) may be implemented with a neutralization plate. In various embodiments, other plasma sources (e.g. remote inductively coupled or microwave plasma sources) can also be used. The plate can eliminate the relatively heavier ions and only allows neutrals to transport to the sample. A 10 sccm Ar and 5 sccm of O₂ is flown into the EWCR to provide the reactive species that interact with the sample. The Ar gas is helpful for gas breakdown initiation and serves as a carrier gas to transport and diffuse O₂. The operating pressure is 1.8 mTorr. Note that the gas flow rate and composition as well as the working pressure can be changed.

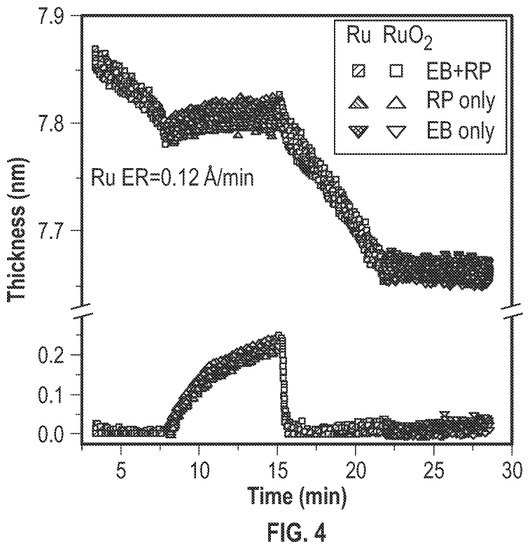

FIG. 4 is a graphical representation of a thickness change of Ru and RuO₂ during sequential treatment of EB and RP, in accordance with an embodiment.

In various embodiments, a sequential process is conducted on Ru film with either simultaneous or individual EB and RP treatment, as shown in FIG. 4. At beginning, simultaneous EB/RP exposure induced consistent Ru etching with an ER of 0.12 Å/min. After switching off EB, Ru etch stopped immediately, and a surface oxide layer is slowly built up, resulting from the partial oxidation of Ru to non-volatile RuO₂ by the oxygen species produced by RP. With the ignition of the EB, the surface RuO₂ can be quickly removed and the Ru etching is restored. During the EB only processing, neither Ru nor Ru oxide is etched or formed, since not enough reactive oxygen species is being produced to oxidize the Ru. Such sequential study indicates that the reactive oxygen neutrals produced by RP partially oxidizes the surface Ru and the EB can further oxidize the surface to volatile RuO₃ or RuO₄. Previous XPS studies on EB/RP treated Si also indicated that EB promotes the oxidation of the Si.

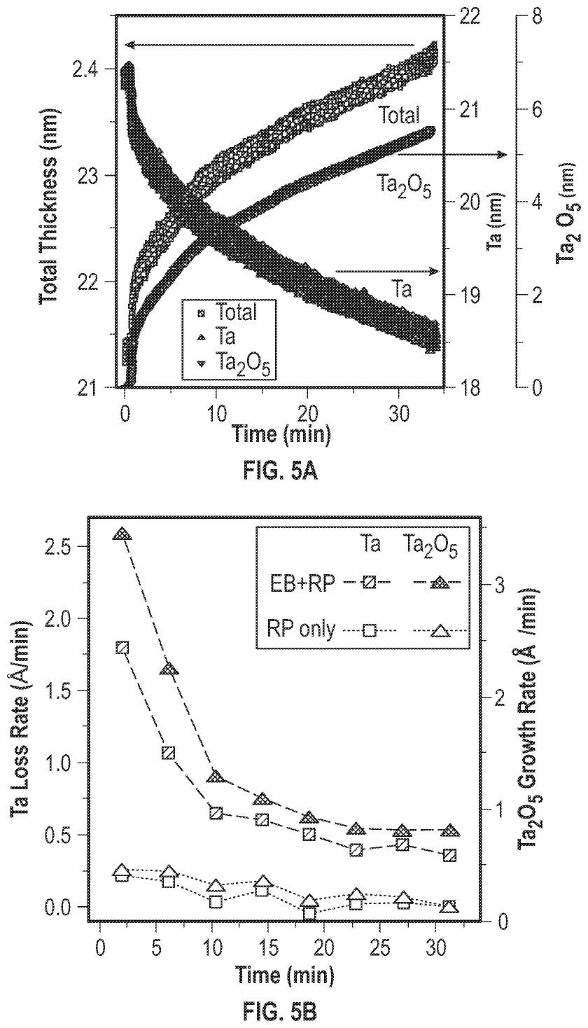

FIG. 5A is a graphical representation of a thickness profile of Ta, Ta₂O₅ and the sum of the two during the concurrent EB and RP exposure, in accordance with an embodiment, and FIG. 5B is a graphical representation of a Ta loss rate and Ta₂O₅ growth rate during the concurrent EB and RP or RP only exposure, in accordance with an embodiment.

The same EB/RP exposure is applied to Ta thin film and the results are shown in FIG. 5A. Rather than Ta etching, Ta is oxidized to dielectric Ta₂O₅, giving a total thickness increase of ˜3 nm after 30 min exposure even though ˜3 nm Ta is lost because of chemical transformation during oxidation to Ta2O₅. The thickness loss of Ta refers to the Ta film that is oxidized, which should not be confused with the overall thickness growth for the Ta sample which is the thickness of the formed Ta oxide (about 6 nm) minus the converted Ta metal. The oxidation rate is reflected from the Ta thickness loss rate and Ta₂O₅ growth rate as shown in FIG. 5B. Both rates diminished with processing time as a thicker Ta₂O₅ layer is formed on the surface. A thicker oxide film makes the electron and oxygen penetration through the oxide film more difficult and fewer reactive oxygen species reach the underlying Ta surface, thus the electron-induced oxidation slows down. FIG. 5B also includes the Ta and Ta₂O₅ thickness change rate induced by RP only as a comparison. The RP induced oxidation is significantly slower than that induced by the concurrent EB/RP irradiation. The oxidation almost stopped after ˜30 min RP exposure when ˜only 0.9 nm Ta2O₅ had been formed. The comparison shown in FIG. 5B indicates that the EB not only enhances the oxidation rate but also allows oxygen species to travel deeper into the surface and extend the oxidation reaction to a remarkable depth. The fact that material growth is significantly enhanced by EB irradiation offers insight in the application of localizing material growth by the EB. The opposite thickness changes on Ru (etching) and Ta (growth) corresponding to the same concurrent EB and RP irradiation provides applications in 3D nanofabrication, where one material (a first material) is etched while a new film grows on another material (a second material), as illustrated in FIG. 1.

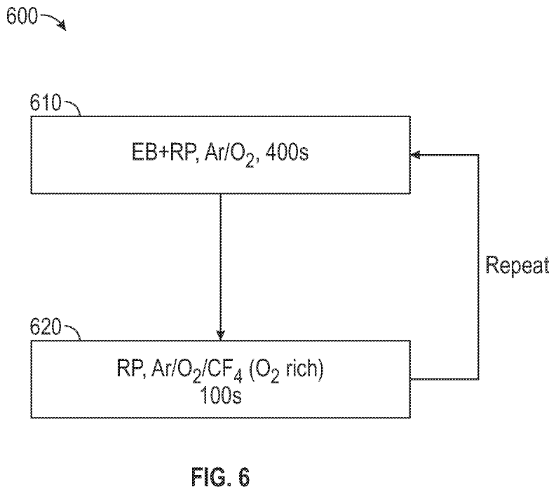

FIG. 6 is a flow diagram of an example method 600 of a cyclic process combining alternative Ar/O₂ EB/RP and Ar/O₂/CF₄ RP, in accordance with an embodiment.

FIG. 6 shows the simultaneous material etching and growth using the combination of EB and RP by controlling the precursor chemistry (element 610). The addition of FC gases, such as CF₄ and C₄F₈, into the plasma source can deposit a FC thin film on the reactor wall. This thin passivation film can reduce the recombination of the plasma-produced oxygen species on reactor chamber walls and improve the transport efficiency of the oxygen species to the sample, leading to the enhancement of the ER. At element 620, a RP only passivation step is employed, during which a small amount of CF₄ is fed to the Ar/O₂ gas. A cyclic process comprising of alternative EB/RP with Ar/O₂ and RP only with Ar/O₂/CF₄ exposure is applied to realize the simultaneous etching and growth on Ru and Ta respectively.

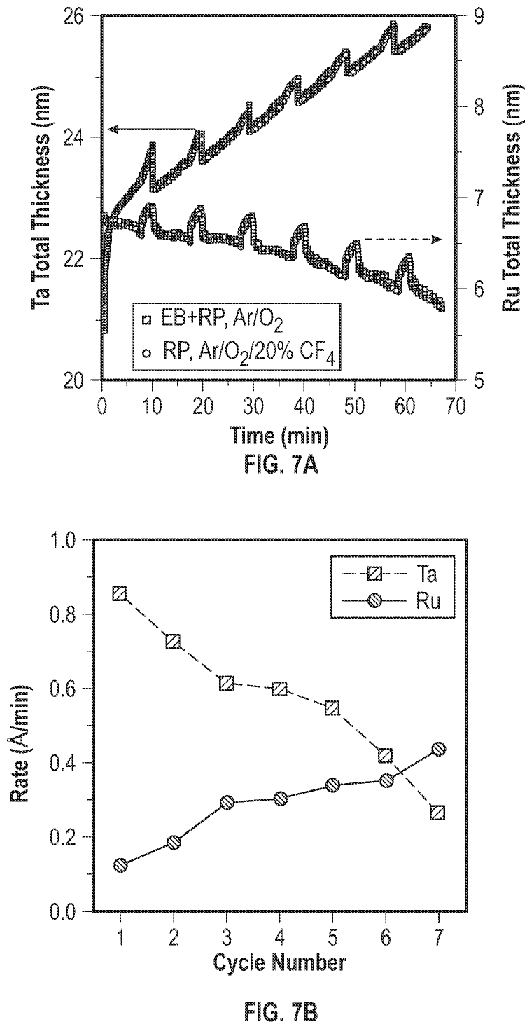

FIG. 7A is a graphical representation of total thickness change of Ru and Ta during the alternative Ar/O₂ EB/RP and Ar/O₂/CF₄ RP, in accordance with an embodiment, and FIG. 7B is a graphical representation of a thickness loss rate of Ru and Ta vs. processing cycle, in accordance with an embodiment.

The change of the total thickness of Ru and Ta for 7 cycles, which is the thickness sum of metal, metal oxide and metal oxyfluoride of Ru and Ta, is shown in FIG. 7A. For an Ru sample, during the EB/RP with Ar/O₂ exposure, Ru etching is observed and the thickness is reduced. With the RP only with Ar/O₂/CF₄ exposure, a thickness increase ascribed to the formation of RuOₓF_{y} is observed. However, upon switching to EB/RP with Ar/O₂, the surface RuOₓF_{y} is removed quickly and Ru etching is restored, similar to the results shown in FIG. 4. The total thickness for the Ru sample decreased after the processing. On the other hand, for Ta sample, the total thickness increases with treatment time due to the oxidation of Ta. During the RP with Ar/O₂/CF₄ exposure, a TaOₓF_{y} film grew on the surface which is removed in a fast manner in the following EB/RP with Ar/O₂ exposure and then the Ta oxidation continued, which is enhanced by the EB as illustrated in FIG. 5A.

The thickness loss rate of the Ru and Ta is compared in FIG. 7B. The Ru loss rate increases with processing cycles, which is ascribed to the chamber passivation by the Ar/O₂/CF₄ RP that enhances the transport of oxygen species to the Ru sample. On the other hand, material growth on the surface, i.e., Ta₂O₅ on Ta, impedes the penetration of the EB, leading to a slowdown of the material growth rate. At cycle 7, the Ru loss rate surpasses that of the Ta and a Ru over Ta removal selectivity is achieved. The selectivity can be further improved by extending the processing cycles. The Ru over Ta selectivity achieved by this approach can be applied to photomask repair, etch of Ru via, etc., where the selective removal of Ru with minimal damage is required.

Accordingly, in various embodiments simultaneous material selective etching and growth is realized by integrating EB and RP sources and controlling the surface and precursor chemistry. Material selective etching and growth of an oxide is determined by the precursor gas and the surface. The simultaneous materials etching and oxide growth characteristics utilizing a simple single set of precursors is promising to simplify certain issues in an overall nanofabrication process and improve the efficiency of producing desirable surface topography consisting of different materials. The self-selective material etching or growth can also be applied to processes where highly selective etching or growth is crucial. This approach can generate a damage-free surface compared to the plasma-induced etching and broaden the selection of precursor reactants in EB induced etching or deposition. The material removal selectivity is also realized by the growth of a surface film that impedes the interaction between the precursors and the underlying surface.

As described herein an approach of combining an EB and RP to realize simultaneous materials etching and growth is detailed in the present disclosure. This approach can simplify the fabrication process where materials etching and growth are done in a series of separate steps in conventional methods, as illustrated in FIG. 1. This approach has great controllability since materials etching and growth can be localized by the EB.

The characteristic of self-selective material etching on one material while material growth takes place on another material can be applied in processes where etch stop is required after the top material is depleted. Materials growth rather than etching will be induced once the bottom material is exposed to the EB and RP, as shown in FIG. 2. In conventional methods, a mask layer is deposited between the two materials to physically impede the etching. This method can achieve the same goal without the additional etch stop layer deposition step.

The realization of Ru loss rate being higher than that of Ta can be applied to a process where Ru etch selectivity is needed, such as photomask repair.

In various embodiments, the electron source used is a flood gun. It can be replaced with any other electron source, including but not limited to hollow cathode electron source, scanning electron microscope, broad-beam electron sources, etc. The DPU might not be necessary, depending on the working condition of the specific electron source. Additionally, the electron irradiated area can be a full wafer. The differential pumping unit might not be necessary for other electron sources.

In various embodiments, the RP source used is an electron cyclotron wave resonance plasma source with a neutralization plate. It can be replaced with any other RP sources, such as inductively coupled plasma, capacitively coupled plasma, helicon plasma, or toroidal and microwave-based RP. The neutralization plate might not be necessary and can be replaced by any other device that achieves effective charge elimination for the surfaces to be functionalized.

The materials used in various embodiments are Ru and Ta and the processing gases are Ar and O₂ with a total flow rate of 15 sccm and a working pressure of 1.8 mTorr. Both the flow rate and the working pressure can be changed. The Ar gas served as a carrier gas, and is helpful for discharge initiation and to diffuse O₂. Other chemically inert gases, such as N₂, He, etc., can be used. O₂ gas is flown to the RP to provide reactive oxygen species to induce Ru etching and oxidation of Ta. The O₂ gas and the Ru and Ta materials can be replaced with other combinations, for instance, EB/RP with Cl₂ induces etching of molybdenum (Mo) but thickness growth on copper (Cu) by forming non-volatile CuCl₂. The idea is that the precursor gas can induce etching on one material and growth on the other material as shown in FIG. 1.

The RP only with Ar/O₂/CF₄ is applied between the EB/RP exposure to passivate the chamber surface so that the recombination of the oxygen species is retarded, leading to higher transport efficiency of oxygen species to the sample. This can induce higher ER on the etched material that surpasses the thickness loss rate of the other material and realize selective material removal. Tetrafluoromethane (CF₄) can be substituted by other HFC or FC gases, such as trifluoromethane (CHF₃), difluoromethane (CF₂H₂), fluoromethane (CH₃F), hexafluorocthane (C₂F₆), etc. The passivation by Ar/O₂/CF₄ with RP can be replaced by other approaches that can selectively enhance the ER, for example, by increasing the etchant concentration. This ER enhancement step might not even be necessary in cases where the ER induced by the EB and RP is already fast, or the selective material removal is not required. Additionally, certain materials can be used for inner chamber wall coating, e.g., Teflon, to increase the lifetime of radicals produced by the remote plasma source.

In an aspect of the disclosure, a method of material-selective etching and growth includes providing an electron beam (EB) source and providing a remote plasma (RP) source. The EBsource and the RP source are applied simultaneously to a device comprising a first material of a first selected area and a second material of a second selected area, wherein the simultaneous application of electron beam irradiation from the EB source and the chemical fluxes from the RP source performs etching of the first material and growth of a third material on the second material by chemical conversion.

In an aspect of the method, the EB source is applied at a material penetration depth to cause the growth of the third material.

In an aspect of the method, the EB source and the RP source are applied for a predefined time period.

In an aspect of the method, the the predefined time period is 400 seconds.

In an aspect of the method, the first material is ruthenium.

In an aspect of the method, the second material is tantalum.

In an aspect of the method, the method further includes discontinuing the application of the EB source.

In an aspect of the method, the growth of the third material includes a growth of the third material of at least 1 nm.

In an aspect of the method, the growth of the third material includes a growth greater than 6 nm.

In an aspect of the method, the RP source is an electron cyclotron wave resonance (EWCR) source.

In an aspect of the method, the RP source is a remote inductively coupled or microwave plasma source.

In an aspect of the method, the device comprising the first material of the first selected area and the second material of the second selected area is not treated prior to application of the EB source and the RP source simultaneously.

In an aspect of the method, the first selected area and the second selected area are not contiguous to one another.

In an aspect of the method, the first selected area and the second selected area are contiguous to one another.

In an aspect of the present disclosure, an apparatus includes an electron beam (EB) source and a remote plasma (RP) source. The EB source and the RP source operate simultaneously operate on a device comprising a first material of a first selected area and a second material of a second selected area, wherein the simultaneous application of electron beam irradiation from the EB source and the chemical fluxes from the RP source performs etching of the first material and growth of a third material on the second material by chemical conversion.

The preceding example aspects and features have been provided for illustration purposes, and applicants hereby reserve the right to claim and protect any subject matter or combination thereof as supported by the present disclosure.

What is claimed is:

1. A method of material-selective etching and growth, comprising:
providing an electron beam (EB) source;
providing a remote plasma (RP) source;
applying the EB source and the RP source simultaneously to a device comprising a first material of a first selected area and a second material of a second selected area, wherein the simultaneous application of electron beam irradiation from the EB source and the chemical fluxes from the RP source performs etching of the first material and growth of a third material on the second material by chemical conversion.

2. The method of claim 1, wherein the EB source is applied at a material penetration depth to cause the growth of the third material.

3. The method of claim 1, wherein the EB source and the RP source are applied for a predefined time period.

4. The method of claim 3, wherein the predefined time period is 400 seconds.

5. The method of claim 1, wherein the first material is ruthenium.

6. The method of claim 1, wherein the second material is tantalum.

7. The method of claim 1, further comprising discontinuing the application of the EB source.

8. The method of claim 1, wherein the growth of the third material includes a growth of the third material of at least 1 nm.

9. The method of claim 8, wherein the growth of the third material includes a growth greater than 6 nm.

10. The method of claim 1, wherein the RP source is an electron cyclotron wave resonance (EWCR) source.

11. The method of claim 1, wherein the RP source is a remote inductively coupled or microwave plasma source.

12. The method of claim 1, wherein the device comprising the first material of the first selected area and the second material of the second selected area is not treated prior to application of the EB source and the RP source simultaneously.

13. The method of claim 1, wherein the first selected area and the second selected area are not contiguous to one another.

14. The method of claim 1, wherein the first selected area and the second selected area are contiguous to one another.

15. An apparatus, comprising:
an electron beam (EB) source; and
a remote plasma (RP) source;
wherein the EB source and the RP source simultaneously operate on a device comprising a first material of a first selected area and a second material of a second selected area, wherein the simultaneous application of electron beam irradiation from the EB source and the chemical fluxes from the RP source performs etching of the first material and growth of a third material on the second material by chemical conversion.
